(19) United States
(12) Patent Application Publication
(10) Pub. No.: US 2025/0142867 A1
(43) Pub. Date: May 1, 2025

(54) SEMICONDUCTOR STRUCTURE

(71) Applicant: Innolux Corporation, Miaoli County (TW)

(72) Inventors: Yuan-Lin Wu, Miaoli County (TW); Kuan-Feng Lee, Miaoli County (TW)

(73) Assignee: Innolux Corporation, Miaoli County (TW)

(21) Appl. No.: 18/896,827

(22) Filed: Sep. 25, 2024

Related U.S. Application Data
(60) Provisional application No. 63/594,961, filed on Nov. 1, 2023.

(30) Foreign Application Priority Data
Jun. 26, 2024 (CN) 202410838754.8

(51) Int. Cl. H01L 29/778; H01L 29/20; H01L 29/66

(52) U.S. Cl. CPC H10D 30/477; H10D 30/015; H10D 62/8503

(57) ABSTRACT

A semiconductor structure including a first epitaxial region, a second epitaxial region, a gate structure, a source region, a source electrode and a drain electrode. The second epitaxial region is disposed on the first epitaxial region. The gate structure is disposed on the second epitaxial region. The source region is disposed on the second epitaxial region and adjacent to the gate structure. The source electrode is disposed on the source region and is electrically connected to the source region. The drain electrode is disposed on the first epitaxial region and is electrically connected to the first epitaxial region. The first epitaxial region includes an impurity region on a side away from the second epitaxial region, and a concentration of impurities included in the impurity region increases with approaching the second epitaxial region.

### CROSS-REFERENCE TO RELATED APPLICATION

This application claims the priority benefit of U.S. provisional application Ser. No. 63/594,961, filed on Nov. 1, 2023 and China application serial no. 202410838754.8, filed on Jun. 26, 2024. The entirety of each of the above-mentioned patent applications is hereby incorporated by reference herein and made a part of this specification.

### BACKGROUND

### Technical Field

The disclosure relates to a semiconductor structure, and in particular relates to vertical high electron mobility transistor (vertical HEMT).

### Description of Related Art

High electron mobility transistor (HEMT) is a semiconductor structure with relatively high breakdown voltage, relatively low impedance, and relatively fast switching frequency. These characteristics make HEMT widely applicable in high-power electronic devices. However, HEMT also has relatively high process cost.

### SUMMARY

A semiconductor structure that has relatively low process cost is provided in some embodiments of the disclosure.

A semiconductor structure provided according to some embodiments of the disclosure includes a first epitaxial region, a second epitaxial region, a gate structure, a source region, a source electrode, and a drain electrode. The second epitaxial region is disposed on the first epitaxial region. The gate structure is disposed on the second epitaxial region. The source region is disposed on the second epitaxial region and adjacent to the gate structure. The source electrode is disposed on the source region and is electrically connected to the source region. The drain electrode is disposed on the first epitaxial region and is electrically connected to the first epitaxial region. The first epitaxial region includes an impurity region on a side away from the second epitaxial region, and a concentration of impurities included in the impurity region increases with approaching the second epitaxial region.

A semiconductor structure provided according to other embodiments of the disclosure includes a first epitaxial region, a second epitaxial region, a gate structure, a body region, a source region, a source electrode, and a drain electrode. The second epitaxial region is disposed on the first epitaxial region. The gate structure is disposed on the second epitaxial region. The body region is disposed on the second epitaxial region and adjacent to the gate structure. The source region is disposed on the body region and adjacent to the gate structure. The source electrode is disposed on the source region and is electrically connected to the source region. The drain electrode is disposed on a side of the first epitaxial region away from the second epitaxial region and is electrically connected to the first epitaxial region. The source region includes a rough surface on a side away from the body region.

In order to make the aforementioned features and advantages of the disclosure comprehensible, embodiments accompanied with drawings are described in detail below.

### BRIEF DESCRIPTION OF THE DRAWINGS

FIG. 1 is a process schematic diagram of a manufacturing method of a semiconductor structure of a first embodiment of the disclosure.

FIG. 2 is a process schematic diagram of a manufacturing method of a semiconductor structure of a second embodiment of the disclosure.

FIG. 3 is a process schematic diagram of a manufacturing method of a semiconductor structure of a third embodiment of the disclosure.

FIG. 4 is a partial cross-sectional schematic diagram of a semiconductor structure of a fourth embodiment of the disclosure.

FIG. 5 is a partial cross-sectional schematic diagram of a semiconductor structure of a fifth embodiment of the disclosure.

FIG. 6A is a partial cross-sectional schematic diagram of a semiconductor structure of a sixth embodiment of the disclosure.

FIG. 6B is a partial cross-sectional schematic diagram of a semiconductor structure of a seventh embodiment of the disclosure.

FIG. 6C is a partial cross-sectional schematic diagram of a semiconductor structure of an eighth embodiment of the disclosure.

FIG. 6D is a partial cross-sectional schematic diagram of a semiconductor structure of a ninth embodiment of the disclosure.

FIG. 6E is a partial cross-sectional schematic diagram of a semiconductor structure of a tenth embodiment of the disclosure.

FIG. 7A is a partial cross-sectional schematic diagram of a semiconductor package of the first embodiment of the disclosure.

FIG. 7B is a partial cross-sectional schematic diagram of a semiconductor package of the second embodiment of the disclosure.

### DETAILED DESCRIPTION OF DISCLOSED EMBODIMENTS

References of the exemplary embodiments of the disclosure are to be made in detail. Examples of the exemplary embodiments are illustrated in the drawings. If applicable, the same reference numerals in the drawings and the descriptions indicate the same or similar parts.

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

Certain terms may be used throughout the disclosure and the appended patent claims to refer to specific elements. It should be understood by those skilled in the art that electronic device manufacturers may refer to the same elements by different names. The disclosure does not intend to distinguish between elements that have the same function but have different names. In the following description and patent claims, words such as “comprising”, “including”, and “having” are open-ended words, so they should be interpreted as meaning “including but not limited to . . . ”. Accordingly, when the terms “comprising”, “including”, and/or “having” are used in the description of this disclosure, they designate the presence of the corresponding feature, region, step, operation and/or component, but do not exclude the presence of one or more of a corresponding feature, region, step, operation, and/or component.

In the disclosure, wordings used to indicate directions, such as “up,” “down,” “front,” “back,” “left,” and “right,” merely refer to directions in the accompanying drawings. Therefore, the directional wordings are used to illustrate rather than limit the disclosure. In the accompanying drawings, the drawings illustrate the general features of the methods, structures, and/or materials used in the particular embodiments. However, the drawings shall not be interpreted as defining or limiting the scope or nature covered by the embodiments. For example, the relative sizes, thicknesses, and locations of the layers, regions, and/or structures may be reduced or enlarged for clarity.

When a corresponding component (e.g., a film layer or region) is referred to as being “on” another component, it may be directly on the other component or other components may be present therebetween. On the other hand, when a component is referred to as being “directly on” another member, there are no components in between unless otherwise stated in the specification. Additionally, when a component is referred to as being “on” another component, the two are in a top-down relationship when viewed from above, and the component may be above or below the other component, depending on the orientation of the device.

The terms “equal to” or “same”, “substantially” or “generally” are interpreted as within 20% of a given value or range, or interpreted as within 10%, 5%, 3%, 2%, 1%, or 0.5% of the given value or range.

The terms such as “first”, “second”, etc. used in the description and the patent claims are used to modify elements, which do not imply and represent that the (or these) elements have any previous ordinal numbers, and also does not represent the order of a certain element and another element, or the order of the manufacturing method. The use of these ordinal numbers is to only clearly distinguish an element with a certain name from another element with the same name. The same terms may not be used in the patent claims and the description, and accordingly, the first component in the description may be the second component in the patent claims.

It should be noted that, in the following embodiments, the features in several different embodiments may be replaced, reorganized, and mixed to complete other embodiments without departing from the spirit of the disclosure. As long as the features of the various embodiments do not violate the spirit of the disclosure or conflict with one another, they may be mixed and matched arbitrarily.

The electrical connection or coupling described in the disclosure may refer to direct connection or indirect connection. In the case of a direct connection, the end points of two elements on a circuit directly connect to each other, or connect to each other through a conductive wire. In the case of indirect connection, a switch, a diode, a capacitor, an inductor, other suitable elements, or a combination thereof, but not limited therein, is between the end points of two elements on a circuit.

In the disclosure, the thickness, length, width, and area may be measured by adopting a measurement method such as an optical microscope (OM), and the thickness may be measured from a cross-sectional image in an electronic microscope, but not limited thereto. In addition, any two values or directions used for comparison may have certain errors. If a first value is equal to a second value, it implies that there may be an error of about 10% between the first value and the second value; if a first direction is perpendicular to a second direction, an angle between the first direction and the second direction may be between 80 degrees and 100 degrees; if the first direction is parallel to the second direction, an angle between the first direction and the second direction may be between 0 degrees and 10 degrees.

The electronic device of the disclosure may be applied to a display device, a light-emitting device, a backlight device, an antenna device, a sensing device or a splicing device, or may be configured to assist the electronic unit to be placed at a specific spacing on the temporary substrate, but not limited thereto. The electronic device may be a bendable or flexible electronic device. The display device may be a non-self-luminous display device or a self-luminous display device. The antenna device may be a liquid crystal antenna device or a non-liquid crystal antenna device, and the sensing device may be a sensing device for sensing capacitance, light, heat or ultrasonic waves, but not limited thereto. Electronic devices may include electronic components such as passive and active components, such as capacitors, resistors, inductors, diodes, transistors, etc. The diode may include a light emitting diode or a photodiode. The light emitting diode (LED) may include, for example, an organic light emitting diode (OLED), a mini light emitting diode (mini LED), a micro light emitting diode (micro LED), or a quantum dot light emitting diode (quantum dot LED), but not limited thereto. The splicing device may be, for example, a display splicing device or an antenna splicing device, but not limited thereto. It should be noted that, the electronic device may be any arrangement and combination of the foregoing, but not limited thereto. In addition, the shape of the electronic device may be rectangular, circular, polygonal, a shape with curved edges, or other suitable shapes.

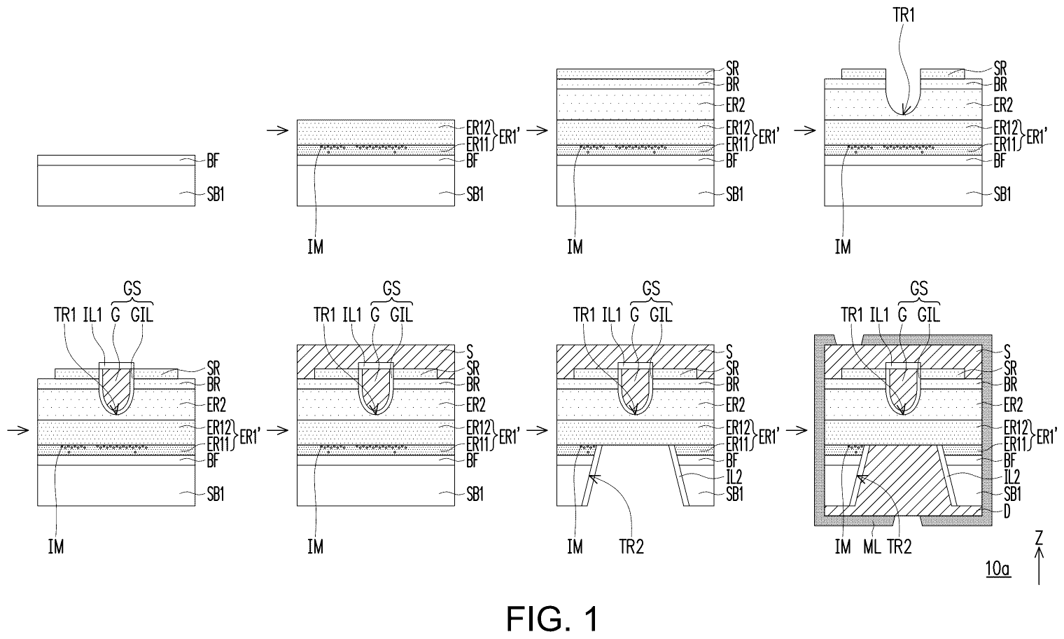

FIG. 1 is a process schematic diagram of a manufacturing method of a semiconductor structure of a first embodiment of the disclosure.

Referring to FIG. 1, in this embodiment, the semiconductor structure 10a may be formed by performing the following steps, but the disclosure is not limited thereto.

Proceed to step (1): forming the buffer layer BF on the (first) substrate SB1.

The material of the substrate SB1 may be, for example, glass, plastic, or a combination thereof. For example, the material of the substrate SB1 may include quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET), or other suitable materials, or a combination thereof, and the disclosure is not limited thereto. In this embodiment, the substrate SB1 is a silicon (111) substrate.

In some embodiments, the buffer layer BF may be formed by performing a metal organic chemical vapor deposition (MOCVD) process, but this disclosure is not limited thereto. In other embodiments, the buffer layer BF may be formed by performing a hydride vapor phase (HVPE) process or a molecular beam epitaxy (MBE) process. The material of the buffer layer BF may be, for example, a III-V semiconductor. For example, the material of the substrate SB1 may include aluminum gallium nitride, but the disclosure is not limited thereto. In addition, the buffer layer BF may be, for example, a single-layer structure or a multi-layer structure, and the disclosure is not limited thereto. In some embodiments, the buffer layer BF may be configured to reduce the difference in lattice constant and thermal expansion coefficient between the substrate SB1 and the first epitaxial region ER1 to be formed subsequently to reduce the possibility of defects in the first epitaxial region ER1.

In some embodiments, before forming the buffer layer BF on the substrate SB1, a nucleation layer (not shown) may be formed on the substrate SB1, but the disclosure is not limited thereto. The material of the nucleation layer may be, for example, aluminum nitride.

Proceed to step (2): forming the first epitaxial region ER1′ on the buffer layer BF. The first epitaxial region ER1′ may be formed, for example, by performing the following steps, but the disclosure is not limited thereto.

Proceed to step (2-a): forming an epitaxial sub-region ER11 on the buffer layer BF by using the recycled gas, in which the epitaxial sub-region ER11 includes impurities IM. In some embodiments, the epitaxial sub-region ER11 may be formed by performing a MOCVD process, but the disclosure is not limited thereto. The material of the epitaxial sub-region ER11 may be, for example, a heavily doped n-type III-V group semiconductor layer. For example, the material of the epitaxial sub-region ER11 may include heavily doped n-type gallium nitride, in which the dopant may be silicon (Si), sulfur(S), selenium (Se), tellurium (Te), or oxygen (O), but this disclosure is not limited thereto. In some embodiments, the concentration of the above-mentioned dopant is 10¹⁹ cm⁻³, but the disclosure is not limited thereto. The recycled gas may be, for example, a purified precursor of tail gas generated during a MOCVD process similar to the formation of the first epitaxial region ER1 in this embodiment. Specifically, the tail gas may include unreacted precursor and/or carrier gas in the above-mentioned MOCVD process. The precursor may include trimethylgallium (Ga(CH₃)₃) and ammonia (NH₃), and the carrier gas may include nitrogen gas (N₂) and/or hydrogen gas (H₂), but the disclosure is not limited thereto.

After the tail gas is purified, the recycled gas (purified precursor) may be obtained. In some embodiments, the purified precursor includes trimethylgallium. However, in addition to trimethylgallium, the purified precursor further includes a portion of residual impurities. Based on this, the epitaxial sub-region ER11 formed using the recycled gas includes impurities IM, in which the impurities IM are, for example, hydrocarbons such as methyl.

In this embodiment, since the recycled gas includes a portion of the impurities IM, and the concentration during the MOCVD process increases with the reaction time due to precursor consumption, therefore, the impurities IM included in the epitaxial sub-region ER11 have a concentration gradient. In detail, the impurities IM included in the epitaxial sub-region ER11 increase along the growth direction (direction Z).

Proceed to step (2-b): forming the epitaxial sub-region ER12 on the epitaxial sub-region ER11. In some embodiments, the epitaxial sub-region ER12 may be formed by performing a MOCVD process, but the disclosure is not limited thereto. The material of the epitaxial sub-region ER12 may be, for example, a heavily doped n-type III-V group semiconductor layer. For example, the material of the epitaxial sub-region ER12 may include heavily doped n-type gallium nitride, in which the dopant may be silicon (Si), sulfur(S), selenium (Se), tellurium (Te), or oxygen (O), but this disclosure is not limited thereto. In some embodiments, the concentration of the above-mentioned dopant is 10¹⁹ cm⁻³, but the disclosure is not limited thereto.

At this point, the forming method of the first epitaxial region ER1′ in this embodiment is completed. The first epitaxial region ER1′ includes an epitaxial sub-region ER11 and an epitaxial sub-region ER12, but the forming method of the first epitaxial region ER1′ of the disclosure is not limited thereto.

Proceed to step (3): sequentially forming the second epitaxial region ER2, the body region BR, and the source region SR on the first epitaxial region ER1.

In some embodiments, the second epitaxial region ER2 may be formed by performing a MOCVD process, but the disclosure is not limited thereto. The material of the second epitaxial region ER2 may be, for example, an n-type III-V group semiconductor layer. For example, the material of the second epitaxial region ER2 may include n-type gallium nitride, in which the dopant may be silicon (Si), sulfur(S), selenium (Se), tellurium (Te), or oxygen (O), but this disclosure is not limited thereto. In some embodiments, the concentration of the above-mentioned dopant is 10¹⁴ cm⁻³, but the disclosure is not limited thereto.

In some embodiments, the body region BR may be formed by performing a MOCVD process, but the disclosure is not limited thereto. The material of the body region BR may be, for example, a p-type III-V semiconductor layer. For example, the material of the body region BR may include p-type gallium nitride, in which the dopant may be magnesium (Mg), carbon (C), beryllium (Be), calcium (Ca), or zinc (Zn), but this disclosure is not limited thereto. In some embodiments, the concentration of the above-mentioned dopant is 10¹⁶ cm⁻³, but the disclosure is not limited thereto.

In some embodiments, the source region SR may be formed by performing a MOCVD process, but the disclosure is not limited thereto. The material of the source region SR may be, for example, a heavily doped n-type III-V group semiconductor layer. For example, the material of the source region SR may include heavily doped n-type gallium nitride, in which the dopant may be silicon (Si), sulfur(S), selenium (Se), tellurium (Te), or oxygen (O), but this disclosure is not limited thereto. In some embodiments, the concentration of the above-mentioned dopant is 10¹⁹ cm⁻³, but the disclosure is not limited thereto.

Proceed to step (4): forming a trench Tr1 in the second epitaxial region ER2, the body region BR, and the source region SR. In some embodiments, the trench Tr1 may be formed by performing a patterning process on the source region SR, the body region BR, and the second epitaxial region ER2, but the disclosure is not limited thereto. In this embodiment, the trench Tr1 is U-shaped as shown in FIG. 1, but the disclosure is not limited thereto.

Proceed to step (5): forming the gate structure GS in the trench Tr1. The gate structure GS may be formed, for example, by performing the following steps, but the disclosure is not limited thereto.

Proceed to step (5-a): forming the gate insulating layer GIL on the sidewall of the trench Tr1. In some embodiments, the gate insulating layer GIL may be formed by performing a chemical vapor deposition (CVD) process, a physical vapor deposition (PVD) process, or an atomic layer deposition (ALD) process, this disclosure is not limited thereto. The material of the gate insulating layer GIL may, for example, include suitable dielectric materials. For example, the materials of the gate insulating layer GIL may include silicon oxide (SiO₂), silicon nitride (Si₃N₄), aluminum oxide (Al₂O₃), tantalum oxide (Ta₂O₅), titanium oxide (TiO₂), zinc oxide (ZnO₂), hafnium oxide (HfO₂), but the disclosure is not limited thereto.

Proceed to step (5-b): forming the gate electrode G in the trench Tr1, in which the gate electrode G is filled in the trench Tr1. In some embodiments, the gate electrode G may be formed by performing a chemical vapor deposition (CVD) process, a physical vapor deposition (PVD) process, or an atomic layer deposition (ALD) process, this disclosure is not limited thereto. The material of the gate electrode G may include, for example, a suitable metal or metal alloy. For example, the material of the gate electrode G may include copper (Cu), aluminum (Al), tungsten (W), nickel (Ni), cobalt (Co), or a combination thereof, but the disclosure is not limited thereto.

In this embodiment, after forming the gate electrode G in the trench Tr1, an insulating layer IL1 is also formed to cover the gate electrode G. Based on this, the insulating layer IL1 and the gate insulating layer GIL may cover the gate electrode G together. The forming method and material of the insulating layer IL1 may be the same as or similar to the forming method and material of the gate insulating layer GIL, and are not repeated herein.

At this point, the forming method of the gate structure GS of this embodiment is completed. The gate structure GS includes a gate electrode G and a gate insulating layer GIL, but the forming method of the gate structure GS of the disclosure is not limited thereto.

Proceed to step (6): forming the source electrode S on the gate structure GS. In some embodiments, the source electrode S may be formed by performing a chemical vapor deposition (CVD) process, a physical vapor deposition (PVD) process, or an atomic layer deposition (ALD) process, this disclosure is not limited thereto. The material of the source electrode S may include, for example, a suitable metal or metal alloy. For example, the material of the source electrode S may include copper (Cu), aluminum (Al), tungsten (W), nickel (Ni), cobalt (Co), or a combination thereof, but the disclosure is not limited thereto.

In this embodiment, the source electrode S is also disposed on the source region SR to be electrically connected to the source region SR.

Proceed to step (7): removing a portion of the substrate SB1, the buffer layer BF1, and the epitaxial sub-region ER11 to form the trench Tr2.

In some embodiments, the trench Tr2 may be formed by performing a patterning process on the substrate SB1, the buffer layer BF1, and the epitaxial sub-region ER11, but the disclosure is not limited thereto. In this embodiment, the trench Tr2 exposes a portion of the epitaxial sub-region ER12.

In this embodiment, after forming the trench Tr2, an insulating layer IL2 is also formed on the sidewall of the trench Tr2. The forming method and material of the insulating layer IL2 may be the same as or similar to the forming method and material of the gate insulating layer GIL, and are not repeated herein.

Proceed to step (8): forming the drain electrode D in the trench Tr2, in which the drain electrode D is filled in the trench Tr2. In some embodiments, the drain electrode D may be formed by performing a chemical vapor deposition (CVD) process, a physical vapor deposition (PVD) process, or an atomic layer deposition (ALD) process, this disclosure is not limited thereto. The material of the drain electrode D may include, for example, a suitable metal or metal alloy. For example, the material of the drain electrode D may include copper (Cu), aluminum (Al), tungsten (W), nickel (Ni), cobalt (Co), or a combination thereof, but the disclosure is not limited thereto.

In this embodiment, the drain electrode D is electrically connected to the epitaxial sub-region ER12 through the trench Tr2.

In this embodiment, after forming the drain electrode D in the trench Tr2, a molding layer ML is also formed. The molding layer ML covers the semiconductor structure 10a and exposes a portion of the source electrode S and the drain electrode D. In some embodiments, the molding layer ML may be formed by performing a suitable molding process, but the disclosure is not limited thereto. The material of the molding layer ML may include suitable organic materials, and the disclosure is not limited thereto.

At this point, the manufacturing method of the semiconductor structure 10a of this embodiment is completed, but the manufacturing method of the semiconductor structure 10a provided by the disclosure is not limited thereto. In this embodiment, by reusing the precursor obtained after purifying the tail gas to perform the forming reaction of the first epitaxial region ER1′, the amount of precursor required for the reaction may be reduced, thereby reducing the process cost of the semiconductor structure 10a.

It is worth noting that although the epitaxial sub-region ER11 includes the impurities IM, it occupies a smaller area relative to the epitaxial sub-region ER12, so the possibility of affecting the electrical properties of the semiconductor structure 10a may be reduced.

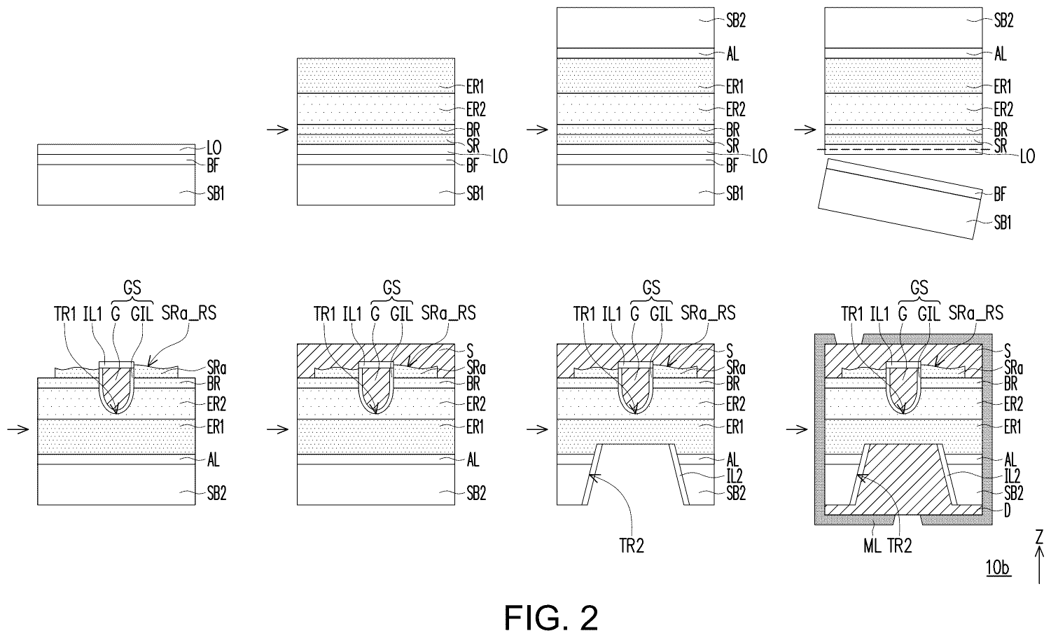

FIG. 2 is a process schematic diagram of a manufacturing method of a semiconductor structure of a second embodiment of the disclosure. It is noted that the embodiment of FIG. 2 may use the reference numerals and a part of the contents of the embodiment of FIG. 1, and the same or similar reference numerals are used to denote the same or similar elements, and the description of the same technical content is omitted.

Referring to FIG. 2, in this embodiment, the semiconductor structure 10b may be formed by performing the following steps, but the disclosure is not limited thereto.

Proceed to step (1): forming the buffer layer BF on the substrate SB1. In this embodiment, after the buffer layer BF is formed on the substrate SB1, a lift-off layer LO is also formed on the buffer layer BF. In some embodiments, the lift-off layer LO may be formed by performing a coating process, a printing process, or a deposition process, but the disclosure is not limited thereto. The material of the lift-off layer LO may include, for example, suitable organic materials, and the disclosure is not limited thereto.

Proceed to step (2′) and step (3′): sequentially forming the source region SR, the body region BR, the second epitaxial region ER2, and the first epitaxial region ER1 on the lift-off layer LO. In some embodiments, the first epitaxial region ER1 may be formed by performing a MOCVD process, but the disclosure is not limited thereto. The material of the first epitaxial region ER1 may be, for example, a heavily doped n-type III-V group semiconductor layer. For example, the material of the first epitaxial region ER1 may include heavily doped n-type gallium nitride, in which the dopant may be silicon (Si), sulfur(S), selenium (Se), tellurium (Te), or oxygen (O), but this disclosure is not limited thereto. In some embodiments, the concentration of the above-mentioned dopant is 10¹⁹ cm⁻³, but the disclosure is not limited thereto.

For detailed descriptions of the source region SR, the body region BR, the second epitaxial region ER2, and the trench Tr1, reference may be made to the above embodiments, and are not repeated herein.

Proceed to step (A): forming the (second) substrate SB2 on the first epitaxial region ER1. For detailed description of the substrate SB2, reference may be made to the substrate SB1 in the above embodiments, and is not repeated herein. In this embodiment, the substrate SB2 is a silicon (100) substrate.

In this embodiment, the substrate SB2 is bonded to the first epitaxial region ER1 through the adhesive layer AL. The material of the adhesive layer may include, for example, suitable conductive materials, and the disclosure is not limited thereto.

Proceed to step (B): separating the buffer layer BF and the source region SR by using the lift-off layer LO. In some embodiments, the buffer layer BF and the source region SR may be separated by mechanical lift-off or laser lift-off, but the disclosure is not limited thereto. It is worth noting that the substrate SB1 is also separated along with the buffer layer BF in this step.

In this embodiment, after separating the buffer layer BF and the source region SR, a portion of the source region SR may be removed. Therefore, a source region SRa including a rough surface SRa_RS may be formed on a side away from the body region BR.

Proceed to step (4) to step (6): forming the trench Tr1 in the second epitaxial region ER2, the body region BR, and the source region SRa, forming the gate structure GS in the trench Tr1, and forming the source electrode S on the gate structure GS. For detailed descriptions of the trench Tr1, the gate structure GS, and the source electrode S, reference may be made to the above embodiments, and are not repeated herein.

Proceed to step (7′): removing a portion of the substrate SB2, the buffer layer BF1, and the first epitaxial region ER1 to form the trench Tr2.

In some embodiments, the trench Tr2 may be formed by performing a patterning process on the substrate SB2, the buffer layer BF1, and the first epitaxial region ER1, but the disclosure is not limited thereto. In this embodiment, the trench Tr2 exposes a portion of the first epitaxial region ER1.

In this embodiment, after forming the trench Tr2, an insulating layer IL2 is also formed on the sidewall of the trench Tr2. The forming method and material of the insulating layer IL2 may be the same as or similar to the forming method and material of the gate insulating layer GIL, and are not repeated herein.

Proceed to step (8): forming the drain electrode D in the trench Tr2, in which the drain electrode D is filled in the trench Tr2. For detailed description of the drain electrode D, reference may be made to the above embodiments, and is not repeated herein.

In this embodiment, after forming the drain electrode D in the trench Tr2, a molding layer ML is also formed. The molding layer ML covers the semiconductor structure 10b and exposes a portion of the source electrode S and the drain electrode D. For detailed description of the molding layer ML, reference may be made to the above embodiments, and is not repeated herein.

At this point, the manufacturing method of the semiconductor structure 10b of this embodiment is completed, but the manufacturing method of the semiconductor structure 10b provided by the disclosure is not limited thereto. In this embodiment, the substrate SB1 is separated from the process of forming the semiconductor structure 10b, and the substrate SB1 may be recycled for use in subsequent processes (e.g., the process of re-manufacturing the semiconductor structure 10b). Since the cost of the substrate SB1 is greater than the cost of the substrate SB2, the process cost of the semiconductor structure 10b may be reduced by recycling the substrate SB1.

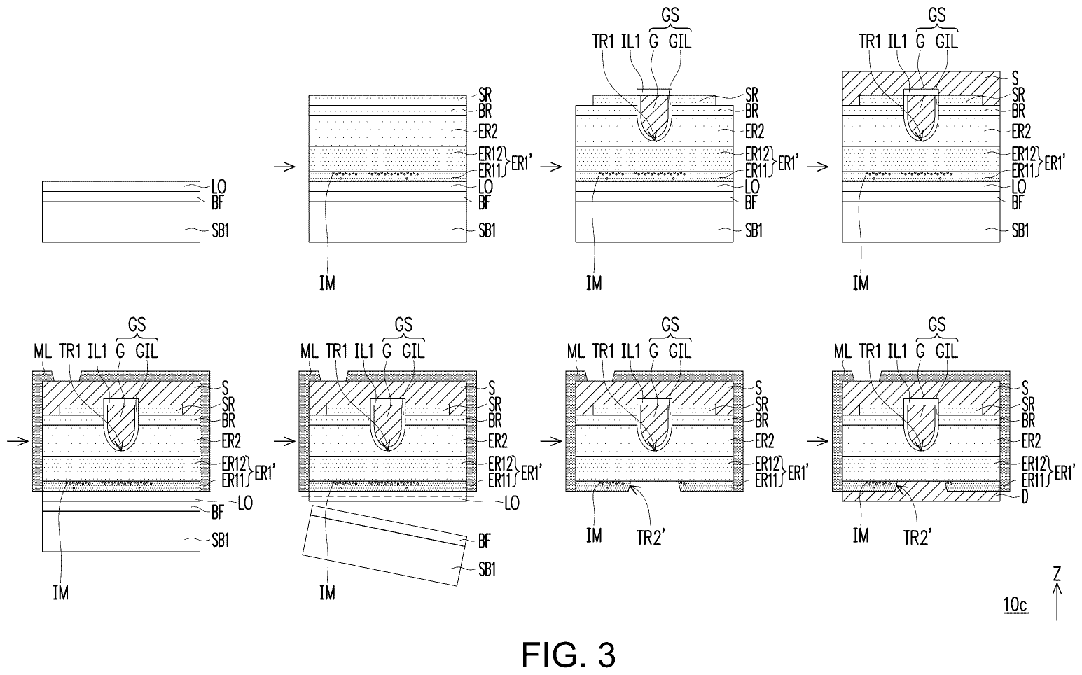

FIG. 3 is a process schematic diagram of a manufacturing method of a semiconductor structure of a third embodiment of the disclosure. It is noted that the embodiment of FIG. 3 may use the reference numerals and a part of the contents of the embodiment of FIG. 1, and the same or similar reference numerals are used to denote the same or similar elements, and the description of the same technical content is omitted.

Referring to FIG. 3, in this embodiment, the semiconductor structure 10c may be formed by performing the following steps, but the disclosure is not limited thereto.

Proceed to step (1) to step (7): forming the buffer layer BF on the substrate SB1; forming a first epitaxial region ER1′ on the buffer layer BF; sequentially forming the second epitaxial region ER2, the body region BR, and the source region SR on the first epitaxial region ER1′; forming the trench Tr1 in the second epitaxial region ER2, the body region BR, and the source region SR; forming the gate structure GS in the trench Tr1; forming the source electrode S on the gate structure GS. In this embodiment, after forming the buffer layer BF on the substrate SB1, a lift-off layer LO is also formed on the buffer layer BF. For detailed descriptions of the substrate SB1, the buffer layer BF, the first epitaxial region ER1′, the second epitaxial region ER2, the body region BR, the source region SR, the trench Tr1, the gate structure GS, the source electrode S, and the lift-off layer LO, reference may be made to the above embodiments, and are not repeated herein.

Proceed to step (C): forming the molding layer ML, in which the molding layer ML covers the first epitaxial region ER1′, the second epitaxial region ER2, the body region BR, the source region SR, the trench Tr1, the gate structure GS, and the source electrode S, and exposing the lift-off layer LO, the buffer layer BF, and the substrate SB1. In some embodiments, the molding layer ML may be formed by performing a suitable molding process, but the disclosure is not limited thereto. The material of the molding layer ML may include suitable organic materials, and the disclosure is not limited thereto.

Proceed to step (B′): separating the buffer layer BF and the first epitaxial region ER1′ by using the lift-off layer LO. In some embodiments, the buffer layer BF and the first epitaxial region ER1′ may be separated by mechanical lift-off or laser lift-off, but the disclosure is not limited thereto. It is worth noting that the first substrate SB1 is also separated along with the buffer layer BF in this step.

Proceed to step (8′): removing a portion of the epitaxial sub-region ER11 to form the trench Tr2′.

In some embodiments, the trench Tr2′ may be formed by performing a patterning process on the epitaxial sub-region ER11, but the disclosure is not limited thereto. In this embodiment, the trench Tr2′ exposes a portion of the epitaxial sub-region ER12.

Proceed to step (9): forming the drain electrode D in the trench Tr2′, in which the drain electrode D is filled in the trench Tr2′. For detailed description of the drain electrode D, reference may be made to the above embodiments, and is not repeated herein.

In this embodiment, after forming the drain electrode D in the trench Tr2′, a portion of the molding layer ML is also removed to expose a portion of the source electrode S.

At this point, the manufacturing method of the semiconductor structure 10c of this embodiment is completed, but the manufacturing method of the semiconductor structure 10c provided by the disclosure is not limited thereto. In this embodiment, the substrate SB1 is separated from the process of forming the semiconductor structure 10c, and the substrate SB1 may be recycled for use in subsequent processes (e.g., the process of re-manufacturing the semiconductor structure 10c). Since the cost of the substrate SB1 is greater than the cost of the substrate SB2, the process cost of the semiconductor structure 10c may be reduced by recycling the substrate SB1.

The structure of the semiconductor structure 10a of this embodiment is briefly introduced below with reference to FIG. 1, but the disclosure is not limited thereto.

Referring to FIG. 1, in this embodiment, the semiconductor structure 10a includes a first epitaxial region ER1′, a second epitaxial region ER2, a gate structure GS, a source region SR, a source electrode S, and a drain electrode D.

The first epitaxial region ER1′ includes, for example, an epitaxial sub-region ER11 and an epitaxial sub-region ER12. The epitaxial sub-region ER11 includes impurities IM, that is, the epitaxial sub-region ER11 may also be referred to as an impurity region. In detail, in this embodiment, the first epitaxial region ER1′ includes an impurity region on a side away from the second epitaxial region ER2, and the concentration of the impurities IM included in the impurity region increases with approaching the second epitaxial region ER2. The impurities IM may be, for example, hydrocarbons such as methyl, but the disclosure is not limited thereto. The material of the first epitaxial region ER1′ includes, for example, a heavily doped n-type III-V group semiconductor layer. In this embodiment, the material of the first epitaxial region ER1′ includes heavily doped n-type gallium nitride, in which the dopant may be silicon (Si), sulfur(S), selenium (Se), tellurium (Te), or oxygen (O), but this disclosure is not limited thereto. For the rest of the description about the first epitaxial region ER1′, reference may be made to the above embodiments, and is not repeated herein.

The second epitaxial region ER2 is, for example, disposed on the first epitaxial region ER1′. The material of the second epitaxial region ER2 includes, for example, an n-type III-V group semiconductor layer. In this embodiment, the material of the second epitaxial region ER2 includes n-type gallium nitride, in which the dopant may be silicon (Si), sulfur(S), selenium (Se), tellurium (Te), or oxygen (O), but this disclosure is not limited thereto. For the rest of the description about the second epitaxial region ER2, reference may be made to the above embodiments, and is not repeated herein.

The gate structure GS is, for example, disposed on the second epitaxial region ER2. In this embodiment, the gate structure GS includes a gate electrode G and a gate insulating layer GIL, in which the gate insulating layer GIL is disposed between the gate electrode G and the second epitaxial region ER2. For the rest of the description about the gate structure GS, reference may be made to the above embodiments, and is not repeated herein.

The source region SR is, for example, disposed on the second epitaxial region ER2, and is, for example, adjacent to the gate structure GS. The material of the source region SR includes, for example, an n-type III-V group semiconductor layer. In this embodiment, the material of the source region SR includes n-type gallium nitride, in which the dopant may be silicon (Si), sulfur (S), selenium (Se), tellurium (Te), or oxygen (O), but this disclosure is not limited thereto. For the rest of the description about the source region SR, reference may be made to the above embodiments, and is not repeated herein.

The source electrode S is, for example, disposed on the source region SR, and is, for example, electrically connected to the source region SR. For the rest of the description about the source electrode S, reference may be made to the above embodiments, and is not repeated herein.

The drain electrode D is, for example, disposed on the first epitaxial region ER1′, and is, for example, electrically connected to the first epitaxial region ER1′. In detail, the drain electrode D is, for example, disposed on a side of the first epitaxial region ER1′ away from the second epitaxial region ER2. Based on this, the semiconductor structure 10a of this embodiment is a vertical high electron mobility transistor (vertical HEMT). For the rest of the description about the drain electrode D, reference may be made to the above embodiments, and is not repeated herein.

In this embodiment, the semiconductor structure 10a further includes a first substrate SB1, a buffer layer BF, and a body region BR.

The first substrate SB1 is, for example, disposed on a side of the first epitaxial region ER1′ away from the second epitaxial region ER2, and is adjacent to the drain electrode D. For the rest of the description about the first substrate SB1, reference may be made to the above embodiments, and is not repeated herein.

The buffer layer BF is, for example, disposed between the first substrate SB1 and the first epitaxial region ER1′. For the rest of the description about the buffer layer BF, reference may be made to the above embodiments, and is not repeated herein.

The body region BR is, for example, disposed between the second epitaxial region ER2 and the source region SR, and is adjacent to the gate structure GS. The material of the body region BR includes, for example, a p-type III-V semiconductor layer. In this embodiment, the material of the body region BR includes p-type gallium nitride, in which the dopant may be magnesium (Mg), carbon (C), beryllium (Be), calcium (Ca), or zinc (Zn), but this disclosure is not limited thereto. For the rest of the description about the body region BR, reference may be made to the above embodiments, and is not repeated herein.

The structure of the semiconductor structure 10b of this embodiment is briefly introduced below with reference to FIG. 2, but the disclosure is not limited thereto.

Referring to FIG. 2, in this embodiment, the semiconductor structure 10b includes a first epitaxial region ER1, a second epitaxial region ER2, a gate structure GS, a body region BR, a source region SRa, a source electrode S, and a drain electrode D. Regarding the first epitaxial region ER1, the second epitaxial region ER2, the gate structure GS, the body region BR, the source electrode S, and the drain electrode D, reference may be made to the above embodiments, and are not repeated herein.

The source region SRa includes, for example, a rough surface SRa_RS on a side away from the body region BR. For the rest of the description about the source region SRa, reference may be made to the above embodiments, and is not repeated herein.

In this embodiment, the semiconductor structure 10b further includes a second substrate SB2 and an adhesive layer AL.

The second substrate SB2 is, for example, disposed on a side of the first epitaxial region ER1 away from the second epitaxial region ER2, and is, for example, adjacent to the drain electrode D. For the rest of the description about the second substrate SB2, reference may be made to the above embodiments, and is not repeated herein.

The adhesive layer AL is, for example, disposed between the second substrate SB2 and the first epitaxial region ER1. For the rest of the description about the adhesive layer AL, reference may be made to the above embodiments, and is not repeated herein.

The structure of the semiconductor structure 10c of this embodiment is briefly introduced below with reference to FIG. 3, but the disclosure is not limited thereto.

Referring to FIG. 3, in this embodiment, the semiconductor structure 10c includes a first epitaxial region ER1′, a second epitaxial region ER2, a gate structure GS, a source region SR, a body region BR, a source electrode S, and a drain electrode D. For the descriptions of the first epitaxial region ER1′, the second epitaxial region ER2, the gate structure GS, the source region SR, the body region BR, the source electrode S, and the drain electrode D, reference may be made to the above embodiments, and are not repeated herein.

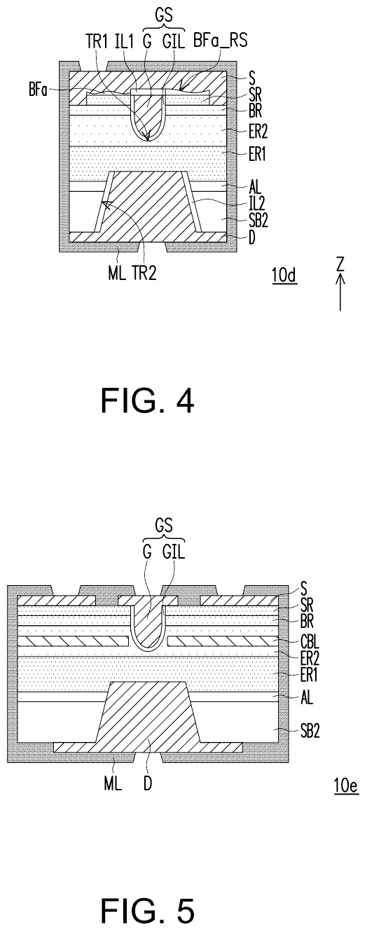

FIG. 4 is a partial cross-sectional schematic diagram of a semiconductor structure of a fourth embodiment of the disclosure. It is noted that the embodiment of FIG. 4 may use the reference numerals and a part of the contents of the embodiment of FIG. 2, and the same or similar reference numerals are used to denote the same or similar elements, and the description of the same technical content is omitted.

Referring to FIG. 4, in this embodiment, the main difference between the semiconductor structure 10d and the semiconductor structure 10b is that the semiconductor structure 10d further includes a buffer layer BFa with a rough surface BFa_RS.

In detail, the lift-off layer LO is formed before the buffer layer BF during the process of forming the semiconductor structure 10d. Therefore, during the lift-off process using the lift-off layer LO, the buffer layer BFa is separated along with the substrate SB1, and a portion of the buffer layer BFa may be removed. Therefore, the buffer layer BFa includes the rough surface BFa_RS on the side away from the source region SR. In this embodiment, the buffer layer BFa may serve as a portion of the source region SR, but the disclosure is not limited thereto.

FIG. 5 is a partial cross-sectional schematic diagram of a semiconductor structure of a fifth embodiment of the disclosure. It is noted that the embodiment of FIG. 5 may use the reference numerals and a part of the contents of the embodiment of FIG. 2, and the same or similar reference numerals are used to denote the same or similar elements, and the description of the same technical content is omitted.

Referring to FIG. 5, in this embodiment, the main difference between the semiconductor structure 10e and the semiconductor structure 10b is that the semiconductor structure 10e further includes a current blocking layer CBL.

The current blocking layer CBL is, for example, disposed in the second epitaxial region ER2, and for example, at least partially overlaps the source region SR. Based on this, the current blocking layer CBL may be configured to first guide the current to a region away from the source region SR to reduce the situation that the current flowing from the drain electrode D to the source electrode S exists densely on a path with low impedance, reducing the possibility of generating a current crowding effect, thereby improving the electrical performance of the semiconductor structure 10e. In this embodiment, the material of the current blocking layer CBL includes silicon oxide, but the disclosure is not limited thereto.

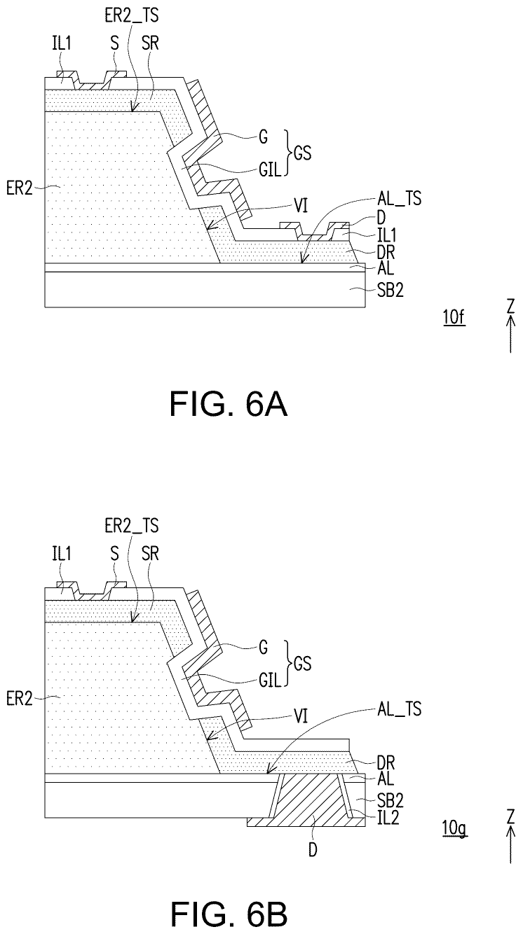

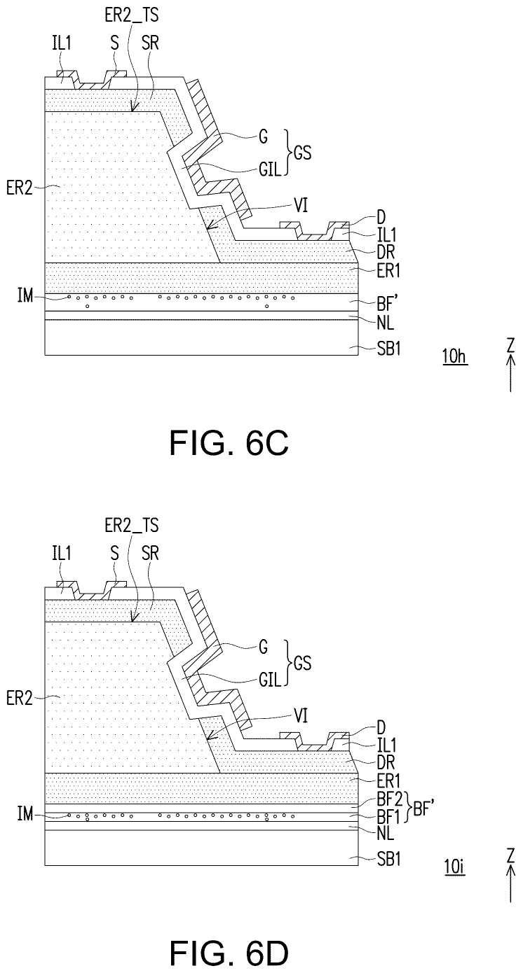

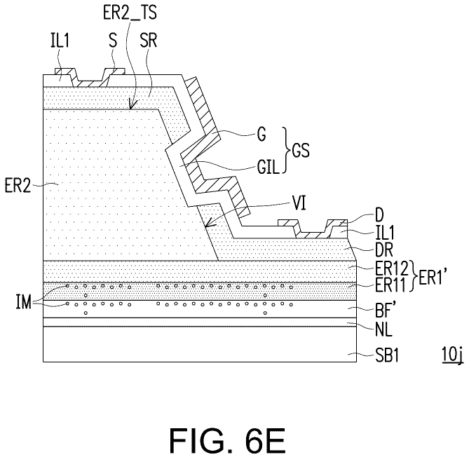

FIG. 6A is a partial cross-sectional schematic diagram of a semiconductor structure of a sixth embodiment of the disclosure. It is noted that the embodiment of FIG. 6A may use the reference numerals and a part of the contents of the embodiment of FIG. 2, and the same or similar reference numerals are used to denote the same or similar elements, and the description of the same technical content is omitted.

Referring to FIG. 6A, in this embodiment, the main difference between the semiconductor structure 10f and the semiconductor structure 10b is that the second epitaxial region ER2 has a vertical interface VI.

The vertical interface VI of the second epitaxial region ER2 may be formed, for example, by performing a lateral etching process on the side surface of the second epitaxial region ER2, but the disclosure is not limited thereto. By forming the vertical interface VI, the semiconductor structure 10f may have a step structure formed of the top surface ER2_TS of the second epitaxial region ER2, the vertical interface VI of the second epitaxial region ER2, and the top surface AL_TS of the adhesive layer AL. In this embodiment, the source electrode S is disposed on the top surface ER2_TS of the second epitaxial region ER2, the gate electrode G is disposed on the vertical interface VI of the second epitaxial region ER2, and the drain electrode D is disposed on the top surface AL_TS of the adhesive layer AL. That is, the gate electrode G, the drain electrode D, and the source electrode S are disposed on the same side of the substrate SB2.

Since the gate electrode G is disposed on the vertical interface VI of the second epitaxial region ER2, the semiconductor structure 10f may have a vertical channel layer (not shown). Based on this, the semiconductor structure 10f is also a vertical high electron mobility transistor.

In this embodiment, the semiconductor structure 10f further includes a drain region DR. The drain region DR is, for example, disposed on the second epitaxial region ER2 and is separated from the source region SR, in which the drain electrode D is electrically connected to the drain region DR. In this embodiment, the drain region DR and the source region SR belong to the same region. That is, the drain region DR and the source region SR include the same material. In this embodiment, the material of the drain region DR and the source region SR includes aluminum gallium nitride, but the disclosure is not limited thereto.

FIG. 6B is a partial cross-sectional schematic diagram of a semiconductor structure of a seventh embodiment of the disclosure. It is noted that the embodiment of FIG. 6B may use the reference numerals and a part of the contents of the embodiment of FIG. 6A, and the same or similar reference numerals are used to denote the same or similar elements, and the description of the same technical content is omitted.

Referring to FIG. 6B, in this embodiment, the main difference between the semiconductor structure 10g and the semiconductor structure 10f is that the drain electrode D and the source electrode S are respectively disposed on opposite sides of the substrate SB2.

FIG. 6C is a partial cross-sectional schematic diagram of a semiconductor structure of an eighth embodiment of the disclosure. It is noted that the embodiment of FIG. 6C may use the reference numerals and a part of the contents of the embodiments of FIG. 1 and FIG. 6A, and the same or similar reference numerals are used to denote the same or similar elements, and the description of the same technical content is omitted.

Referring to FIG. 6C, in this embodiment, the main difference between the semiconductor structure 10h and the semiconductor structure 10f is that the buffer layer BF′ includes impurities IM, and the concentration of the impurities IM increases with approaching the first epitaxial region ER1.

Specifically, in this embodiment, the nucleation layer NL, the buffer layer BF′, and the first epitaxial region ER1 are sequentially disposed on the substrate SB1. The material of the nucleation layer NL is, for example, aluminum nitride, but the disclosure is not limited thereto. The buffer layer BF′ is formed, for example, by using recycled gas (purified precursor). Therefore, the buffer layer BF′ includes the impurities IM, and the impurities IM included in the buffer layer BF′ increase, for example, along the growth direction (direction Z). The material of the first epitaxial region ER1 is, for example, undoped gallium nitride, but the disclosure is not limited thereto.

FIG. 6D is a partial cross-sectional schematic diagram of a semiconductor structure of a ninth embodiment of the disclosure. It is noted that the embodiment of FIG. 6D may use the reference numerals and a part of the contents of the embodiment of FIG. 6C, and the same or similar reference numerals are used to denote the same or similar elements, and the description of the same technical content is omitted.

Referring to FIG. 6D, in this embodiment, the main difference between the semiconductor structure 10i and the semiconductor structure 10h is that the buffer layer BF′ includes a buffer sub-layer BF1 and a buffer sub-layer BF2 stacked in sequence, in which the buffer sub-layer BF1 includes impurities IM.

Specifically, in this embodiment, the buffer sub-layer BF1 and the buffer sub-layer BF2 may be sequentially formed on the substrate SB1, in which the buffer sub-layer BF1 is formed by using recycled gas (purified precursor). Based on this, the region of the impurities IM included in the buffer layer BF′ may be relatively reduced to further reduce the possibility of affecting the electrical properties of the semiconductor structure 10i.

FIG. 6E is a partial cross-sectional schematic diagram of a semiconductor structure of a tenth embodiment of the disclosure. It is noted that the embodiment of FIG. 6E may use the reference numerals and a part of the contents of the embodiment of FIG. 6C, and the same or similar reference numerals are used to denote the same or similar elements, and the description of the same technical content is omitted.

Referring to FIG. 6E, in this embodiment, the main difference between the semiconductor structure 10j and the semiconductor structure 10h is that the epitaxial sub-region E11 in the first epitaxial region ER1′ further includes impurities IM, and the concentration of the impurities IM increases with approaching the second epitaxial region ER2.

In detail, in this embodiment, the epitaxial sub-region E11 in the first epitaxial region ER1′ may also be formed by using recycled gas (purified precursor).

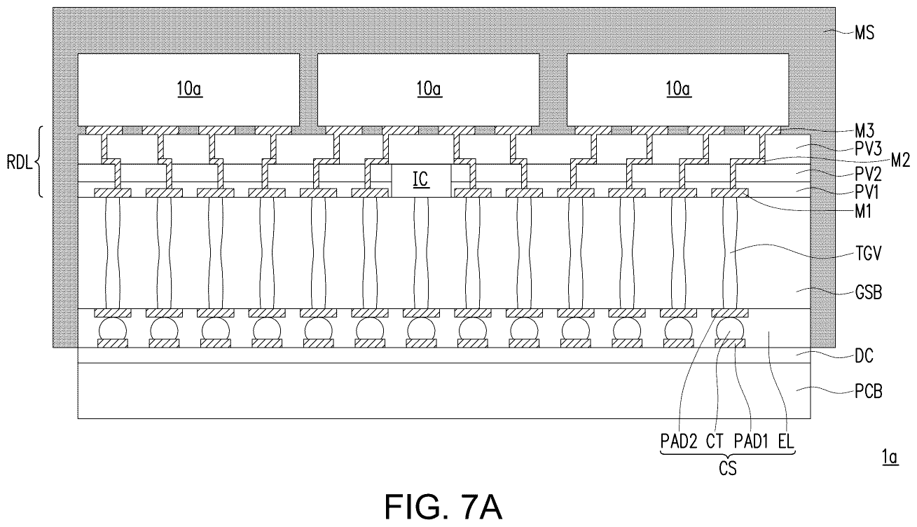

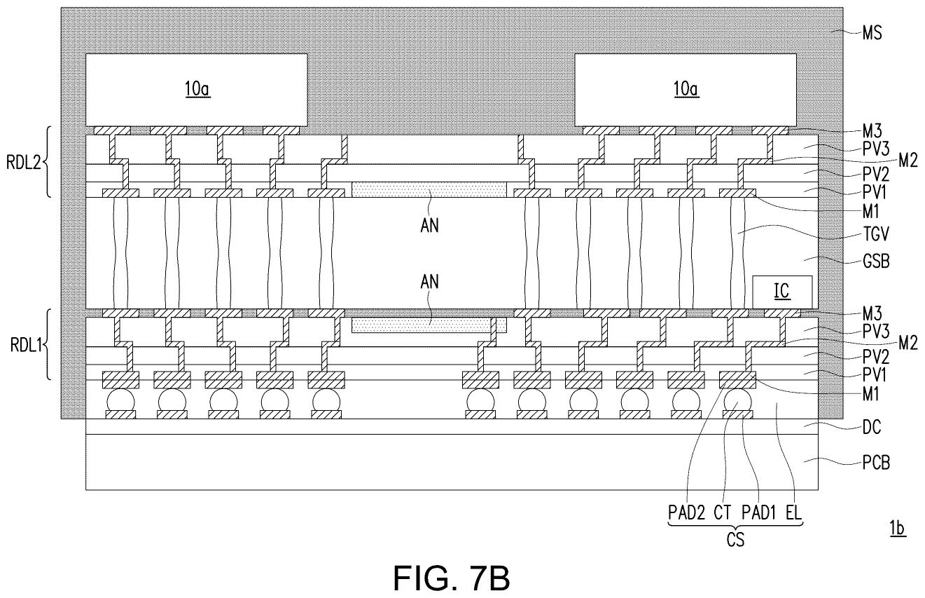

FIG. 7A is a partial cross-sectional schematic diagram of a semiconductor package of the first embodiment of the disclosure. It is noted that the embodiment of FIG. 7A may use the reference numerals and a part of the contents of the embodiment of FIG. 1, and the same or similar reference numerals are used to denote the same or similar elements, and the description of the same technical content is omitted.

Referring to FIG. 7A, in this embodiment, the semiconductor package 1a includes a circuit board PCB, a driving circuit layer DC, a glass substrate GSB, a redistribution layer RDL, a chip IC, multiple semiconductor structures 10a, and a molding structure MS.

A circuit board PCB may, for example, be configured to carry structures disposed thereon. In some embodiments, the circuit board PCB may be a ball grid array (BGA) printed circuit board, but the disclosure is not limited thereto.

The driving circuit layer DC is, for example, disposed on the circuit board PCB, and is, for example, electrically connected to the circuit board PCB. In some embodiments, the driving circuit layer DC may include multiple transistors (not shown), multiple conductive wires (not shown), and multiple insulating layers (not shown), but the disclosure is not limited thereto.

The glass substrate GSB is, for example, disposed on the driving circuit layer DC. In this embodiment, the glass substrate GSB includes multiple through glass vias TGV. The through glass vias TGV in the glass substrate GSB may be electrically connected to each other through the connection structure CS disposed between the glass substrate GSB and the driving circuit layer DC. In detail, the connection structure CS may include, for example, multiple pads PAD1, multiple pads PAD2, multiple conductive terminals CT, and an encapsulation layer EL. The pads PAD1 are, for example, electrically connected to the driving circuit layer DC, the pads PAD2 are, for example, respectively electrically connected to the corresponding through glass via TGV, and the conductive terminals CT are, for example, respectively electrically connected to the corresponding pad PAD1 and pad PAD2. The conductive terminal CT may be, for example, a solder ball as shown in FIG. 7A, but the disclosure is not limited thereto. The encapsulation layer EL covers, for example, the pads PAD1, the pads PAD2, and the conductive terminals CT.

The redistribution layer RDL is, for example, disposed on the glass substrate GSB. In this embodiment, the redistribution layer RDL includes a metal layer M1, an insulating layer PV1, a metal layer M2, an insulating layer PV2, a metal layer M3, and an insulating layer PV3 disposed in sequence. The metal layer M1 is electrically connected to the through glass vias TGV in the glass substrate GSB. The insulating layer PV1 includes, for example, an opening that exposes the metal layer M1, so that the metal layer M2 may be electrically connected to the metal layer M1, and the insulating layer PV2 includes, for example, an opening that exposes the metal layer M2, so that the metal layer M3 may be electrically connected to the metal layer M2.

In some embodiments, an element layer (not shown) may be disposed between the glass substrate GSB and the redistribution layer RDL. The element layer may include multiple transistors (not shown), in which the transistors are electrically connected to the redistribution layer RDL. In some embodiments, the material of the semiconductor layer (not shown) in the transistor may include amorphous silicon, low temperature polycrystalline silicon (LTPS), metal oxides, other suitable materials, or a combination thereof (e.g., a combination of low temperature polycrystalline silicon and metal oxide, that is, low temperature polycrystalline silicon oxide (LTPO)), in which the metal oxide may include indium gallium zinc oxide (IGZO), but this disclosure is not limited thereto.

The chip IC is, for example, disposed on the glass substrate GSB. In some embodiments, the chip IC may include a micro integrated circuit chip (micro IC). For example, the chip IC may include a suitable semiconductor chip such as an application specific integrated circuit chip, an analog chip, a digital chip, a voltage regulator chip, a sensor chip, and/or a memory chip, etc., but the disclosure is not limited thereto. In some embodiments, the chip IC may include an integrated circuit made using a silicon wafer as a base material; or may include an integrated circuit (glass IC) made using glass as a base material, but the disclosure is not limited thereto. In this embodiment, the chip IC may be electrically connected to the driving circuit layer DC through the through glass vias TGV in the glass substrate GSB.

The semiconductor structures 10a are, for example, disposed on the redistribution layer RDL. In this embodiment, the semiconductor structures 10a are electrically connected to the metal layer M3 exposed by the insulating layer PV3 in the redistribution layer RDL. For detailed description of the semiconductor structure 10a, reference may be made to the above embodiments, and is not repeated herein.

It is worth noting that the semiconductor structures 10b to 10j of the above embodiments may also be applied to the semiconductor package 1a of this embodiment, and the disclosure is not limited thereto.

The molding structure MS, for example, covers the circuit board PCB, the driving circuit layer DC, the glass substrate GSB, the redistribution layer RDL, the chip IC and the semiconductor structures 10a to protect the internal elements of the semiconductor package 1a.

FIG. 7B is a partial cross-sectional schematic diagram of a semiconductor package of the second embodiment of the disclosure. It is noted that the embodiment of FIG. 7B may use the reference numerals and a part of the contents of the embodiment of FIG. 7A, and the same or similar reference numerals are used to denote the same or similar elements, and the description of the same technical content is omitted.

Referring to FIG. 7B, in this embodiment, the main difference between the semiconductor package 1b and the semiconductor package 1a is that the semiconductor package 1b includes antenna elements AN.

The antenna elements AN are, for example, disposed on opposite sides of the glass substrate GSB, but the disclosure is not limited thereto. In some embodiments, the antenna element AN includes an antenna patch, but the disclosure is not limited thereto.

In this embodiment, the redistribution layer RDL′ includes a first redistribution layer RDL1 and a second redistribution layer RDL2 disposed on opposite sides of the glass substrate GSB. For detailed description of the redistribution layer RDL′, reference may be made to the above embodiments, and is not repeated herein.

To sum up, in some embodiments of the disclosure, the precursor obtained after purifying the tail gas is used again to perform the forming reaction of the first epitaxial region and/or the buffer layer, so that the amount of precursor required for the reaction to form the first epitaxial region and/or the buffer layer may be reduced, thereby reducing the process cost of the semiconductor structure provided by the disclosure.

Furthermore, in other embodiments of the disclosure, by separating the relatively high-cost substrate from the process of forming semiconductor structures, the substrate may be recycled for use in subsequent processes, thereby the process cost of the semiconductor structure provided by the disclosure may be reduced by recycling the substrate.

What is claimed is:

1. A semiconductor structure, comprising:
a first epitaxial region;
a second epitaxial region, disposed on the first epitaxial region
a gate structure, disposed on the second epitaxial region;
a source region, disposed on the second epitaxial region and adjacent to the gate structure;
a source electrode, disposed on the source region and electrically connected to the source region; and
a drain electrode, disposed on the first epitaxial region and electrically connected to the first epitaxial region,
wherein the first epitaxial region comprises an impurity region on a side away from the second epitaxial region, and a concentration of impurities comprised in the impurity region increases with approaching the second epitaxial region.

2. The semiconductor structure according to claim 1, further comprising:
a first substrate, disposed on a side of the first epitaxial region away from the second epitaxial region and adjacent to the drain electrode; and
a buffer layer, disposed between the first substrate and the first epitaxial region.

3. The semiconductor structure according to claim 2, wherein the buffer layer comprises the impurities, and the concentration of the impurities increases with approaching the first epitaxial region.

4. The semiconductor structure according to claim 1, wherein the drain electrode is disposed on a side of the first epitaxial region away from the second epitaxial region.

5. The semiconductor structure according to claim 1, wherein the gate structure comprises:
a gate electrode; and
a gate insulating layer, disposed between the gate electrode and the second epitaxial region.

6. The semiconductor structure according to claim 1, further comprising:
a body region, disposed between the second epitaxial region and the source region, and adjacent to the gate structure,
wherein the body region comprises a p-type III-V semiconductor layer.

7. The semiconductor structure according to claim 1, further comprising:
a drain region, disposed on the second epitaxial region and separated from the source region, wherein the drain electrode is electrically connected to the drain region.

8. The semiconductor structure according to claim 1, further comprising:
a molding layer, covering the first epitaxial region, the second epitaxial region, and the source region, and exposing a portion of the source electrode and the drain electrode.

9. The semiconductor structure according to claim 1, wherein the first epitaxial region and the source region comprise a heavily doped n-type III-V group semiconductor layer, and the second epitaxial region comprises an n-type III-V group semiconductor layer.

10. The semiconductor structure according to claim 1, wherein the impurities comprise hydrocarbons.

11. A semiconductor structure, comprising:
a first epitaxial region;
a second epitaxial region, disposed on the first epitaxial region;
a gate structure, disposed on the second epitaxial region;
a body region, disposed on the second epitaxial region and adjacent to the gate structure;
a source region, disposed on the body region and adjacent to the gate structure;
a source electrode, disposed on the source region and electrically connected to the source region; and
a drain electrode, disposed on a side of the first epitaxial region away from the second epitaxial region and electrically connected to the first epitaxial region,
wherein the source region comprises a rough surface on a side away from the body region.

12. The semiconductor structure according to claim 11, wherein the source region comprises a heavily doped n-type III-V group semiconductor layer, and the heavily doped n-type III-V group semiconductor layer comprises the rough surface.

13. The semiconductor structure according to claim 11, wherein the source region comprises a heavily doped n-type III-V group semiconductor layer and a buffer layer, and the buffer layer comprises the rough surface.

14. The semiconductor structure according to claim 11, further comprising:
a second substrate, disposed on a side of the first epitaxial region away from the second epitaxial region and adjacent to the drain electrode; and
an adhesive layer, disposed between the second substrate and the first epitaxial region.

15. The semiconductor structure according to claim 11, wherein the drain electrode is disposed on a side of the first epitaxial region away from the second epitaxial region.

16. The semiconductor structure according to claim 11, wherein the second epitaxial region comprises a current blocking layer.

17. The semiconductor structure according to claim 11, wherein the gate structure comprises:
a gate electrode; and
a gate insulating layer, disposed between the gate electrode and the second epitaxial region.

18. The semiconductor structure according to claim 11, wherein the body region comprises a p-type III-V semiconductor layer.

19. The semiconductor structure according to claim 11, further comprising:
a drain region, disposed on the second epitaxial region and separated from the source region, wherein the drain electrode is electrically connected to the drain region.

20. The semiconductor structure according to claim 11, further comprising:
a molding layer, covering the first epitaxial region, the second epitaxial region, and the source region, and exposing a portion of the source electrode and the drain electrode.
